(19) United States
(12) Patent Application Publication
(10) Pub. No.: US 2024/0250054 A1
(43) Pub. Date: Jul. 25, 2024

(54) BARRIER FOR LIQUID METAL THERMAL INTERFACE MATERIAL IN AN ELECTRONIC DEVICE

(71) Applicant: NVIDIA CORPORATION, Santa Clara, CA (US)

(72) Inventors: Malcolm GUTENBURG, San Francisco, CA (US); David HALEY, Beaverton, OR (US); Yunseok KIM, Pleasanton, CA (US); Amit KULKARNI, San Jose, CA (US)

(21) Appl. No.: 18/414,292

(22) Filed: Jan. 16, 2024

Related U.S. Application Data
(60) Provisional application No. 63/480,653, filed on Jan. 19, 2023.

(51) Int. Cl. H01L 23/00; H01L 23/367; H01L 25/18; H10B 80/00

(52) U.S. Cl. CPC H01L 24/26; H01L 23/367; H01L 24/29; H01L 24/32; H01L 25/18; H01L 2224/26175; H01L 2224/29105; H01L 2224/29109; H01L 2224/29111; H01L 2224/32221; H01L 2924/1432; H01L 2924/16196; H01L 2924/16235; H01L 2924/16251; H01L 2924/19041; H01L 2924/19105; H10B 80/00

(57) ABSTRACT

An electronic device comprises: a printed circuit board; an integrated circuit that is coupled to the printed circuit board on a first side and a thermal solution on a second side; a thermal interface material that is disposed between the integrated circuit and the thermal solution; and a first barrier seal that is disposed around a perimeter of the integrated circuit and is electrically insulative.

### CROSS-REFERENCE TO RELATED APPLICATIONS

This application claims priority benefit of the United States Provisional Patent Application titled, “BARRIER FOR LIQUID METAL THERMAL INTERFACE MATERIAL IN AN ELECTRIC DEVICE,” filed on Jan. 19, 2023, and having Ser. No. 63/480,653. The subject matter of this related application is hereby incorporated herein by reference.

### BACKGROUND

### Field of the Various Embodiments

Embodiments of the present invention relate generally to computer systems and, more specifically, to a barrier for liquid metal thermal interface material in an electronic device.

### Description of the Related Art

In modern computing devices, central processing units (CPUs), graphics processing units (GPUs), and other integrated circuits (ICs) generate significant quantities of heat during operation. This heat needs to be removed from the computing devices to prevent thermal damage to the integrated circuits and/or computing devices themselves. For example, a single high-power chip, such as a CPU or GPU, can generate hundreds of watts of heat during operation, and, if this heat is not removed from the computing device in which the high-power chip resides, the temperature of the chip can increase to a point at which the chip is at risk of being thermally damaged. To prevent thermal damage during operation, many systems implement clock-speed throttling when the operating temperature of a processor exceeds a certain threshold. Thus, in these types of systems, the processing speed of the high-power chip is constrained by both the chip design and how effectively heat is removed from the computing device in which the high-power chip resides.

To reduce the impact that thermal constraints have on high-power chip performance, heatsinks can be employed that allow high-power chips to operate at greater processing speeds and generate greater amounts of heat. As is well-understood, a heatsink transfers heat from a chip to the surrounding air, and the air then carries the heat away from the chip and out of the computing device in which the chip resides. To enhance thermal conductivity between a high-power chip and its associated heatsink, a thermal interface material (TIM) is oftentimes disposed between a top surface of the high-power chip and the heatsink.

As high-power chips increase in computational performance, the TIM can become a limiting factor in how effectively these chips can be cooled because the thermal conductivity and thickness of the TIM determine how well the TIM transfers thermal energy from a given high-power chip to its associated heatsink. Accordingly, increasing the thermal conductivity and reducing the thickness of TIMs can increase the thermal and computational performance of high-power chips. The use of liquid metal TIMs, such as materials that includes high amounts of gallium, indium and tin, have been found to have increased thermal conductivity and reduced thickness compared to previous types of TIMs. Thus, liquid metal TIMs have enabled improved thermal and computational performance in high-power chips.

One drawback of liquid metal TIMs, however, is that liquid metal TIMs are electrically conductive and, therefore, can cause electrical shorting if displaced from being located in between a high-power chip and an associated heatsink. For example, capacitors or other electrical components that are mounted on the same packaging substrate as the high-power chip can come into contact with excess or leaked liquid metal TIM, which can create electrical shorts between the inputs and outputs of the electrical components and damage the electrical components and/or the high-power chip itself. Similarly shorting caused by excess or leaked liquid metal TIM that is present on a printed circuit board (PCB) can damage or destroy the PCB and/or the high-speed chip or other chips or electrical components mounted thereon.

Another drawback of liquid-metal TIMs is that, during operation in high-humidity and/or high-temperature environments, liquid-metal TIMs can be oxidized or otherwise chemically degraded by exposure to moisture and/or oxygen. For example, gallium-indium-tin-based TIMs are known to form gallium hydroxide in the presence of humidity. This type of chemical degradation can substantially reduce the thermal conductivity of the liquid-metal TIM, which, in turn, reduces the total thermal performance of the heat exchanger that is coupled to a given high-performance chip via the liquid-metal TIM.

As the foregoing illustrates, what is needed in the art are more effective techniques for employing liquid-metal TIMs with high-power chips.

### SUMMARY

An electronic device comprises: a printed circuit board; an integrated circuit that is coupled to the printed circuit board on a first side and a thermal solution on a second side; a thermal interface material that is disposed between the integrated circuit and the thermal solution and includes a liquid metal; and a seal that is disposed around a perimeter of the integrated circuit and is electrically insulative.

At least one technical advantage of the disclosed design relative to the prior art is that the disclosed design prevents exposure of a liquid-metal TIM to moisture and/or other contaminants that can react with and alter the thermal conductivity of the liquid-metal TIM. Another technical advantage is that excess or leaked liquid-metal TIM cannot come into contact with capacitors or other electrical components that are mounted on the same packaging substrate as a high-power chip that is thermally coupled to a thermal solution via the liquid-metal TIM. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual cross-section of an integrated circuit mounted on a PCB and coupled to a heatsink, in accordance with the prior art.

FIG. 2 is a conceptual illustration of a computer system configured to implement one or more aspects of the various embodiments.

FIG. 3 is a conceptual illustration of an electronic device that includes a heatsink, a liquid-metal TIM, and a dual barrier seal, according to various embodiments.

FIG. 4 is a conceptual plan view of the electronic device of FIG. 3 with a heatsink removed to show a liquid-metal TIM and a dual barrier seal, according to various embodiments.

FIG. 5 is a conceptual cross-section of an electronic device that includes a heatsink, a liquid-metal TIM, and a dual-barrier seal, according to various embodiments.

FIG. 6 is a conceptual cross-section of an electronic device that includes a heatsink, a liquid-metal TIM, and a dual-barrier seal, according to various embodiments.

FIG. 7 is a conceptual cross-section of an electronic device that includes heatsink, liquid-metal TIM, and a single barrier seal, according to various embodiments,

FIG. 8 is a conceptual cross-section of an electronic device that includes a thermal solution thermally coupled to a lidded IC package, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skill in the art that the inventive concepts may be practiced without one or more of these specific details.

### Overview of the Prior Art

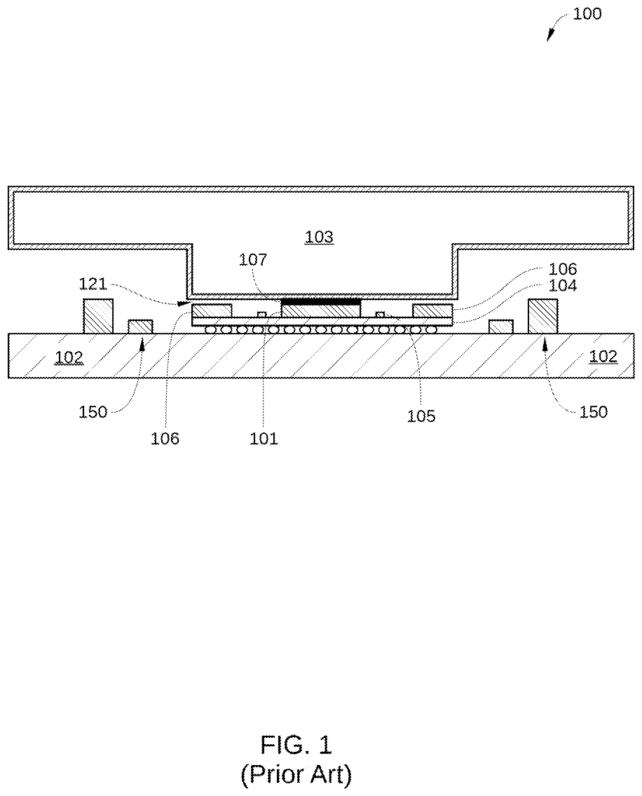

FIG. 1 is a conceptual cross-section of an IC 101 (such as a CPU, GPU, or other processor) mounted on a printed circuit board (PCB) 102 and coupled to a heatsink 103, in accordance with the prior art. Other electronic components 150 are also mounted on PCB 102, such as memory devices and/or power devices associated with IC 101. As shown, IC 101 is mounted on a packaging substrate 104, along with various other electronic components 105, such as capacitors. Frequently, a stiffener 106 is coupled to packaging substrate 104 to mechanically stiffen packaging substrate 104. Together, the above components form an electronic device 100.

IC 101 is thermally coupled to heatsink 103 via a liquid-metal thermal interface material (TIM) 107, which has excellent thermal conductivity, but also is electrically conductive. Because liquid-metal TIM 107 is not a solid material, in some instances liquid-metal TIM 107 can leak onto packaging substrate 104 and/or excess liquid-metal TIM 107 can be deposited onto packaging substrate 104. In either case, because liquid-metal TIM 107 is electrically conductive, electronic components 105 can be electrically shorted when liquid-metal TIM 107 comes in contact therewith.

FIG. 1 further shows an air gap 121 between heatsink 103 and stiffener 106 and/or packaging substrate 104. Air gap 121 is typically present so that stiffener 106 does not contact heatsink 103 even when heatsink 103, stiffener 106, and/or other components within electronic device 100 vary dimensionally within specified tolerance limits. Air gap 121 also prevents stiffener 106 from exerting pressure on heatsink 103 in a direction away from IC 101 when stiffener 106 heats up and expands. Contact between heatsink 103 and stiffener 106 and/or pressure against heatsink 103 in a direction away from IC 101 is highly undesirable, because heat transfer increases between heatsink 103 and IC 101 when heatsink 103 is pressed with greater force against IC 101. Conversely, such heat transfer decreases when heatsink 103 is pressed with less force against IC 101. However, the presence of air gap 121 allows humidity, oxygen, and other potential contaminants to contact liquid-metal TIM 107, which can cause oxidation of liquid-metal TIM 107 and/or other chemical degradation of liquid-metal TIM 107. For example, when liquid-metal TIM 107 is a gallium-indium-tin-based TIM, the presence of humidity adjacent to liquid-metal TIM 107 can result in the formation of gallium hydroxide, and such chemical degradation can greatly decrease the thermal conductivity of liquid-metal TIM 107.

### Overview of Barrier Seal Concept

According to various embodiments, one or more barrier seals are included in an electronic device that includes one or more high-power ICs that are thermally coupled to a heatsink or other thermal solution. Examples of such electronic devices include CPU cards and GPU cards. In some embodiments, the barrier seal(s) prevent shorting that can be caused by leaking or excess liquid-metal TIM. Alternatively or additionally, in some embodiments, the barrier seal(s) prevent exposure of the liquid-metal TIM to humidity and/or other contaminants that can chemically react with the liquid-metal TIM. Furthermore, the barrier seal(s) enable such advantages without compromising the thermal performance of the liquid-metal TIM.

In some embodiments, multiple barrier seals are employed within the electronic device. In such embodiments a first barrier seal prevents shorting of electronic components that are proximate the high-power IC, such as the topside capacitors that are mounted on the same packaging substrate as the high-power IC and/or other ICs that are mounted on the same printed circuit board as the high-power IC. Further, in such embodiments, a second barrier prevents humidity, air, and/or other contaminants from entering the region of the electronic device proximate the liquid-metal TIM. Alternatively, in some embodiments, a single barrier seal is employed that includes properties of the first and second barriers. Examples of such embodiments are described below.

### System Overview

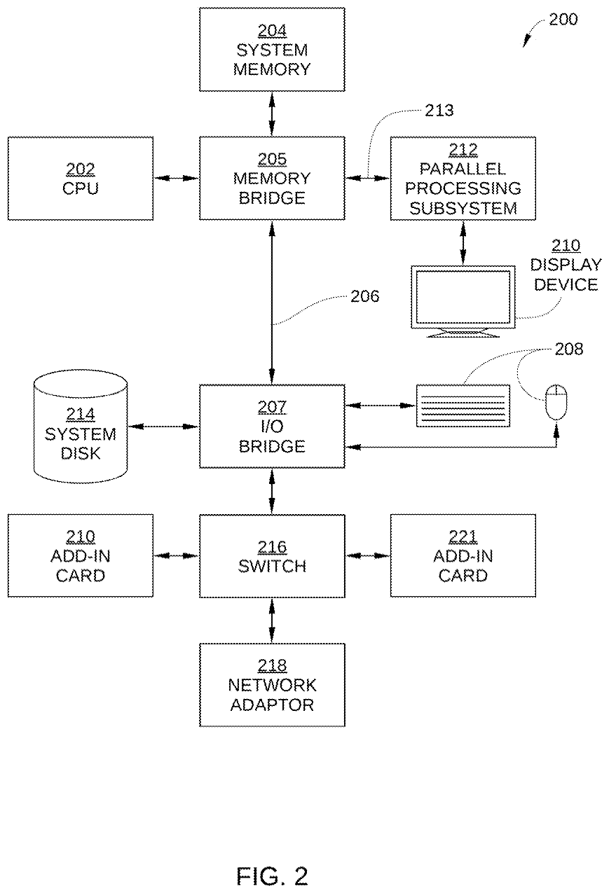

FIG. 2 is a block diagram illustrating a computer system 200 configured to implement one or more aspects of the various embodiments. As shown, computer system 200 includes, without limitation, a central processing unit (CPU) 202 and a system memory 204 coupled to a parallel processing subsystem 212 via a memory bridge 205 and a communication path 213. Memory bridge 205 is further coupled to an I/O (input/output) bridge 207 via a communication path 206, and I/O bridge 207 is, in turn, coupled to a switch 216.

In operation, I/O bridge 207 is configured to receive user input information from input devices 208, such as a keyboard or a mouse, and forward the input information to CPU 202 for processing via communication path 206 and memory bridge 205. Switch 216 is configured to provide connections between I/O bridge 207 and other components of the computer system 200, such as a network adapter 218 and various add-in cards 220 and 221.

As also shown, I/O bridge 207 is coupled to a system disk 214 that may be configured to store content and applications and data for use by CPU 202 and parallel processing subsystem 212. As a general matter, system disk 214 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid state storage devices. Finally, although not explicitly shown, other components, such as universal serial bus or other port connections, compact disc drives, digital versatile disc drives, film recording devices, and the like, may be connected to I/O bridge 207 as well.

In various embodiments, memory bridge 205 may be a Northbridge chip, and I/O bridge 207 may be a Southbrige chip. In addition, communication paths 206 and 213, as well as other communication paths within computer system 200, may be implemented using any technically suitable protocols, including, without limitation, AGP (Accelerated Graphics Port), HyperTransport, or any other bus or point-to-point communication protocol known in the art.

In some embodiments, parallel processing subsystem 212 comprises a graphics subsystem that delivers pixels to a display device 210 that may be any conventional cathode ray tube, liquid crystal display, light-emitting diode display, or the like. In such embodiments, the parallel processing subsystem 212 incorporates circuitry optimized for graphics and video processing, including, for example, video output circuitry. Such circuitry may be incorporated across one or more parallel processing units (PPUs) included within parallel processing subsystem 212. In other embodiments, the parallel processing subsystem 212 incorporates circuitry optimized for general purpose and/or compute processing. Again, such circuitry may be incorporated across one or more PPUs included within parallel processing subsystem 212 that are configured to perform such general purpose and/or compute operations. In yet other embodiments, the one or more PPUs included within parallel processing subsystem 212 may be configured to perform graphics processing, general purpose processing, and compute processing operations. In various embodiments, parallel processing subsystem 212 may be integrated with one or more of the other elements of FIG. 2 to form a single system. For example, parallel processing subsystem 212 may be integrated with CPU 202 and other connection circuitry on a single chip to form a system on chip (SoC).

System memory 204 includes at least one device driver configured to manage the processing operations of the one or more PPUs within parallel processing subsystem 212. In addition, system memory 204 includes a logic circuit analyzer 230, a netlist 240, and timing tables 250. Logic circuit analyzer 230 may be implemented as a set of program instructions loaded in system memory 204 that may be executed by CPU 202. Logic circuit analyzer 230, netlist 240, and timing tables 250 are described in greater detail below.

It will be appreciated that the system shown herein is illustrative and that variations and modifications are possible. The connection topology, including the number and arrangement of bridges, the number of CPUs 202, and the number of parallel processing subsystems 212, may be modified as desired. For example, in some embodiments, system memory 204 is connected to CPU 202 directly rather than through memory bridge 205, and other devices communicate with system memory 204 via memory bridge 205 and CPU 202. In other alternative topologies, parallel processing subsystem 212 may be connected to I/O bridge 207 or directly to CPU 202, rather than to memory bridge 205. In still other embodiments, I/O bridge 207 and memory bridge 205 may be integrated into a single chip instead of existing as one or more discrete devices. Lastly, in certain embodiments, one or more components shown in FIG. 2 may not be present. For example, switch 216 may be eliminated, and network adapter 218 and add-in cards 220, 221 connect directly to I/O bridge 207.

### Dual-Barrier Seal Embodiment

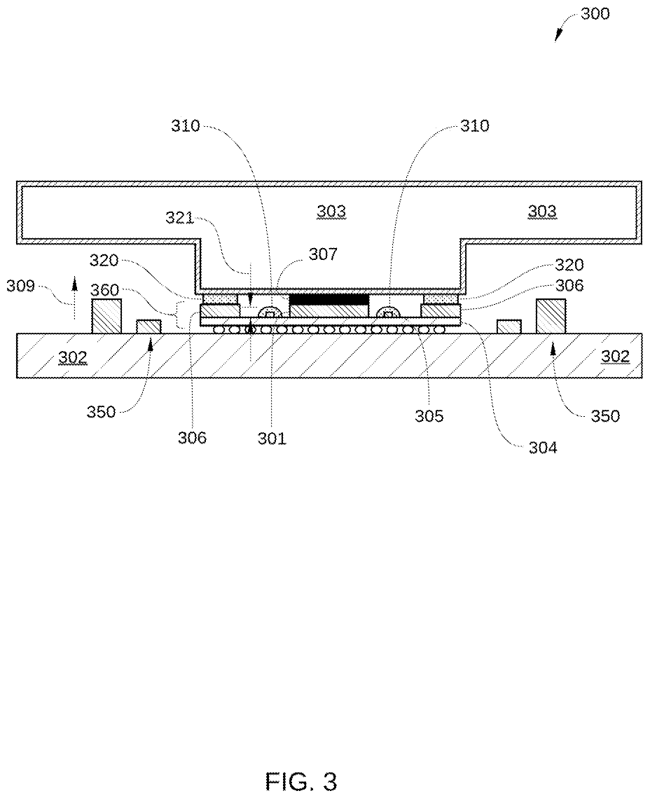

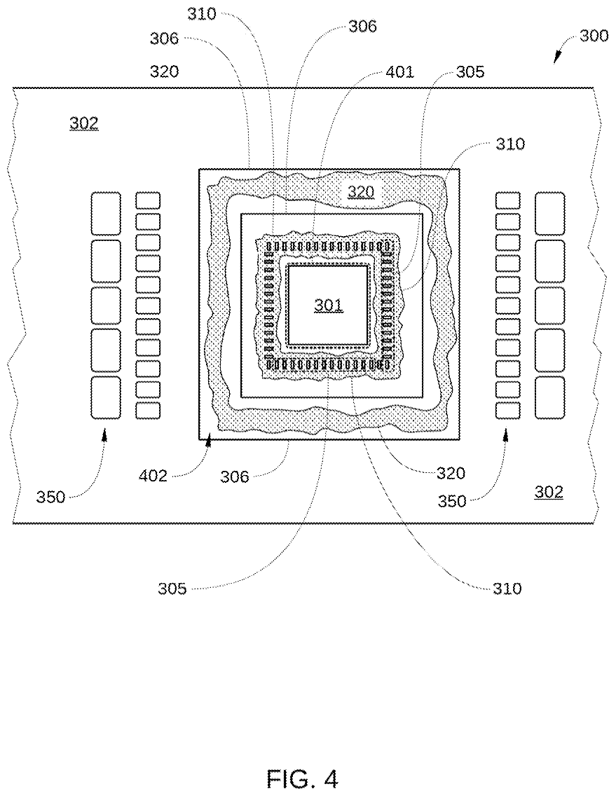

As noted above, in some embodiments, a first barrier seal prevents shorting of electronic components that are proximate the high-power IC and a second barrier prevents the liquid-metal TIM from being exposed to humidity, air, and/or other contaminants. One such embodiment is described below in conjunction with FIGS. 3 and 4.

FIG. 3 is a conceptual illustration of an electronic device 300 that includes a heatsink 303, a liquid-metal TIM 307, and a dual barrier seal, according to various embodiments. FIG. 4 is a conceptual plan view of electronic device 300 with heatsink 303 removed to show a liquid-metal TIM 307 and a dual barrier seal, according to various embodiments. In some embodiments, electronic device 300 can be implemented as CPU 102, parallel processing subsystem 212, and/or add-in cards 220, 221 in FIG. 2.

Electronic device 300 includes an IC 301 (such as a CPU, GPU, or other processor) mounted on a PCB 302 and coupled to a heatsink 303, for example via mounting screws (not shown) that press heatsink 303 against IC 301. Other electronic components 350 are also mounted on PCB 302, such as memory devices and/or power devices associated with IC 301. As shown, IC 301 is mounted on a packaging substrate 304, along with various other electronic components 305, such as capacitors. In the embodiment illustrated in FIG. 3, electronic device 300 further includes a stiffener 306 that is coupled to packaging substrate 304 to mechanically stiffen packaging substrate 304. Together, IC 301, packaging substrate 304, and stiffener 306 form an IC package 360 that is mounted on PCB 302.

IC 301 is thermally coupled to heatsink 303 via a liquid-metal TIM 307, such as a liquid metal that includes gallium, indium, and/or tin or one or more other electrically conductive constituents. To prevent shorting of electronic components 305 and/or any other devices mounted on packaging substrate 304 by excess or leaked liquid-metal TIM 307 or electrically conductive constituents included therein, electronic device 300 includes a first barrier seal 310 that is formed or deposited on electronic components 305 as shown. In some embodiments, first barrier seal 310 is an electrically insulative material that can encapsulate or otherwise insulate electronic components 305 from leaked or excess liquid-metal TIM 307. Thus, first barrier seal 310 acts as a physical barrier from the excess liquid-metal TIM (or electrically conductive constituents included therein) which can spill out from the GPU die during assembly, and/or leak at other times.

Generally, first barrier seal 310 can be any non-conductive, solid, conformal coating that can be applied to, deposited on, or formed on electronic components 305. In some embodiments, first barrier seal 310 includes a solid epoxy material that can be applied as a liquid or paste to electronic components 305 during assembly of electronic device 300. In such embodiments, the liquid or paste hardens upon curing, thereby forming a liquid-tight and electrically insulative seal on electronic components 305. In some embodiments, first barrier seal 310 includes a one-part UV curing silicone, such as N-Sil 8901LM2, which is available from Colltech Group of Santa Clara, California, and is elastic and flexible when cured. Alternatively or additionally, in some embodiments, first barrier seal 310 includes a thermally or chemically cured epoxy.

As shown in FIG. 4, first barrier seal 310 is formed outside a perimeter 401 (dashed lines) of IC 301. Further, in some embodiments, first barrier seal 310 has a height 321 (shown in FIG. 3) that is less than that of IC 301. In such embodiments, first barrier seal 310 does not contact heatsink 303, and therefore thermal expansion of electronic components 305, heatsink 303, and/or packaging substrate 304 does not result in force being exerted against heatsink 303 and away from IC 301. As a result, the presence of first barrier seal 310 does not degrade the thermal performance of IC 301 and heatsink 303.

To prevent humidity, oxygen, and/or other contaminants from reacting with and/or contaminating liquid-metal TIM 307, electronic device 300 includes a second barrier seal 320 that is formed or deposited outside perimeter 401 of IC 301. In the embodiment illustrated in FIGS. 3 and 4, second barrier seal 320 is disposed in or completely fills a region between heatsink 303 and IC package 360 that corresponds to air gap 121 in FIG. 1. Thus, in such embodiments, second barrier seal 320 is formed or deposited on a surface of IC package 360, such as surface 402 of stiffener 306 (or in some cases a surface of packaging substrate 304). In some embodiments, second barrier seal 320 includes a moisture-resistant material and can be deposited to form an air-tight seal around perimeter 401. Thus, second barrier seal 320 acts as a barrier to air and/or air-borne contaminants from reaching liquid-metal TIM 307. As a result, oxidation, hydrolysis, or other chemical degradation of liquid-metal TIM 307, or any other unwanted chemical reactions, are prevented. It is noted that, to act as a barrier to air-borne contaminants, second barrier seal 320 is formed entirely and continuously around perimeter 401 of IC 301, as shown in FIG. 4 and fills an air gap (not shown) disposed between, for example, surface 402 of stiffener 306 and an opposing surface of heatsink 303 (such as the surface of heatsink 303 that faces IC 301).

In the embodiments described above, second barrier seal 320 acts as a barrier to air and/or air-borne contaminants from reaching liquid-metal TIM 307. In other embodiments, liquid-metal TIM 307 can instead be a TIM that does not include a liquid metal. In such embodiments, second barrier seal 320 can act as a barrier to air, air-borne contaminants, a liquid (such as a cooling liquid), or other fluid from reaching the TIM. For example, in an embodiment in which electronic device 300 is immersion cooled via an immersion fluid, second barrier seal 320 prevents deleterious interactions (such as hydrolysis and/or oxidation) between the immersion fluid and the TIM.

In some embodiments, second barrier seal 320 includes a material that, when heated during operation of electronic device 300, exerts little or no pressure on heatsink 303 in a direction 309 away from IC 301. Thus, even though there is no air gap between heatsink 303 and stiffener 306 (or in some cases packaging substrate 304), thermal expansion of head sink 303, stiffener 306, and/or packaging substrate 304 does not cause significant force to be exerted against heatsink 303 in direction 309 by second barrier seal 320. For example, in some embodiments, second barrier seal 320 is formed from a material that partially or completely changes phase when heated during operation of electronic device 300. In such embodiments, when stiffener 306 and heatsink 303 heat up and expand during operation of electronic device 300, second barrier seal 320 softens significantly or changes to a liquid or quasi-liquid state, and therefore can be displaced by the thermal expansion of heatsink 303 and stiffener 306 without exerting significant force on heatsink 303 in direction 309. Examples of suitable materials include certain wax-based substances and low-melting-point adhesives and/or polymers, such as low-temperature “hot-melt” materials that have a melting point on the order of about 100 C. For example, in such embodiments, second barrier seal 320 includes a material that has a softening temperature that is less than or equal to an operating temperature of IC 301. In some embodiments, second barrier seal 320 includes a hot melt polyolefin such as TECHNOMELT AS 8998 (e), which is available from Henkel Corporation of Pittsburgh, Pennsylvania and is a hot melt adhesive. Alternatively, in some embodiments, second barrier seal 320 can be a material of sufficient elasticity that thermal expansion of headsink 303, stiffener 306, and/or packaging substrate 304 generates little or no force on heatsink 303 in direction 309 during the operation and concomitant heating of IC 301.

In some embodiments, second barrier seal 320 includes a hot-melt material, such a material can be applied at high temperature to a suitable surface within electronic device 300 (such as on surface 402 of stiffener 306) and cured in place. For example, in some embodiments, the hot-melt material is applied as a liquid or paste at a high temperature to surface 402 of stiffener 306, then heatsink 303 is attached to PCB 302 and the material contacts heatsink 303 in a continuous line around perimeter 401. IC 301 is then powered on and a workload is run so that IC 301 reaches and maintains a targeted curing temperature, such as 80 C, for a specified curing interval, such as 5-10 minutes. In other embodiments, after the hot-melt material is applied as a liquid or paste to surface 402 of stiffener 306, the targeted curing temperature is achieved in an oven for the specified curing interval. During the curing interval, the material used to form second barrier seal 320 softens and forms an air-tight seal with heatsink 303.

It is noted that the material selected for second barrier seal 320 acts as a humidity barrier both when in a solid state and in a liquid or quasi-liquid state. Thus, second barrier seal 320 prevents intrusion of moisture while in the liquid or quasi-liquid state. It is further noted that the material selected for second barrier seal 320 has sufficient viscosity and surface tension when in the liquid or quasi-liquid state to remain within the gap between heatsink 303 and stiffener 306. Any material that has the above properties when elevated to temperatures associated with operation of electronic device 300 can be employed as second barrier seal 320.

In the above-described embodiments, IC 301 of electronic device 300 is coupled to heatsink 303. In other embodiments, heatsink 303 can be any suitable thermal solution that can be coupled to IC 301, such as a vapor chamber, a liquid cold plate, and the like.

### Alternative Dual-Barrier Seal Embodiment

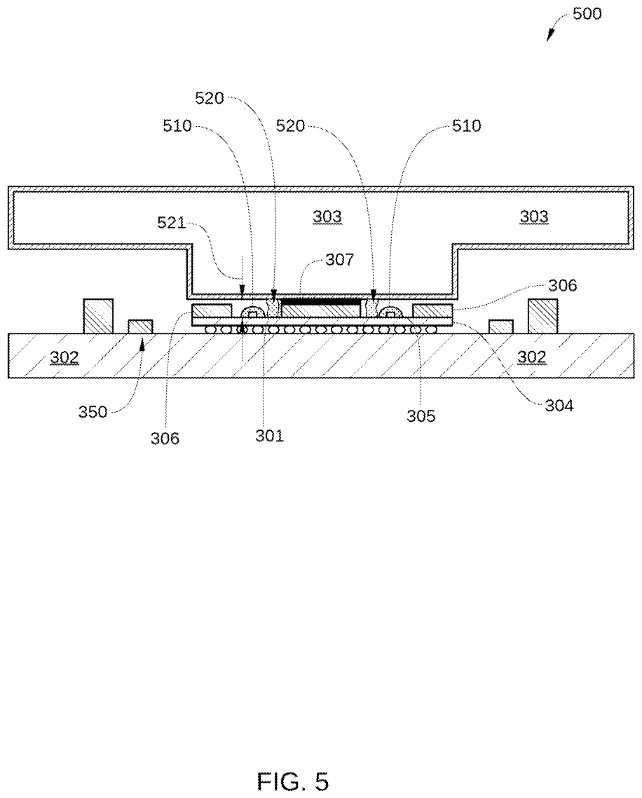

In some embodiments, an oxygen and humidity barrier is disposed between a high-powered IC and an electrically insulative barrier that protects electronic components from shorting. One such embodiment is described below in conjunction with FIG. 5.

FIG. 5 is a conceptual cross-section of an electronic device 500 that includes a thermal solution 503, a liquid-metal TIM 307, and a dual barrier seal, according to various embodiments. Similar to the embodiment described above in conjunction with FIGS. 3 and 4, electronic device 500 includes a first barrier seal 510, which is consistent with first barrier seal 310 of FIG. 3, and a second barrier seal 520 that is formed outside a perimeter of IC 301. However, in the embodiment illustrated in FIG. 5, second barrier seal 520 is disposed between first barrier seal 510 and IC 301. In such embodiments, second barrier seal 520 is formed with a height 521 that is sufficient to contact thermal solution 503 as shown. Thus, in such embodiments, second barrier seal 520 is disposed between and contacts a surface of thermal solution 503 and a surface of packaging substrate 304 to fill a gap therebetween.

### Co-Located Dual-Barrier Seal Embodiment

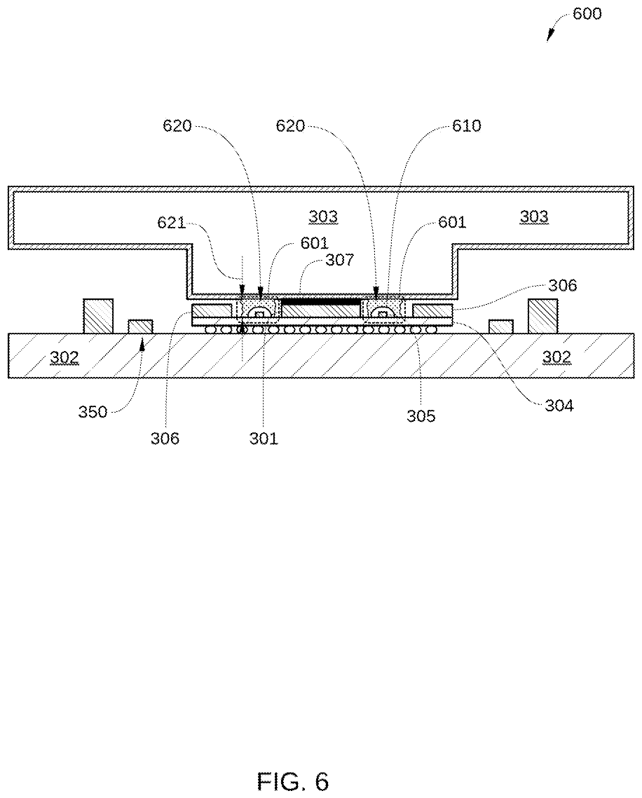

In some embodiments, an oxygen and humidity barrier is collocated with an electrically insulative barrier that protects electronic components from shorting. One such embodiment is described below in conjunction with FIG. 6.

FIG. 6 is a conceptual cross-section of an electronic device 600 that includes a thermal solution 603, a liquid-metal TIM 307, and a dual-barrier seal 601, according to various embodiments. Dual-barrier seal 601 includes a first barrier seal 610, which is consistent with first barrier seal 310 of FIG. 3, and a second barrier seal 620 that is formed in contact with and/or around first barrier seal 610, as shown. In such embodiments, second barrier seal 620 is formed with a height 621 that is sufficient to contact thermal solution 603 as shown and form an air-tight seal. In such embodiments, the materials and formation of second barrier seal 620 can be consistent with those of second barrier seal 320 of FIG. 3.

### Single-Barrier Seal Embodiment

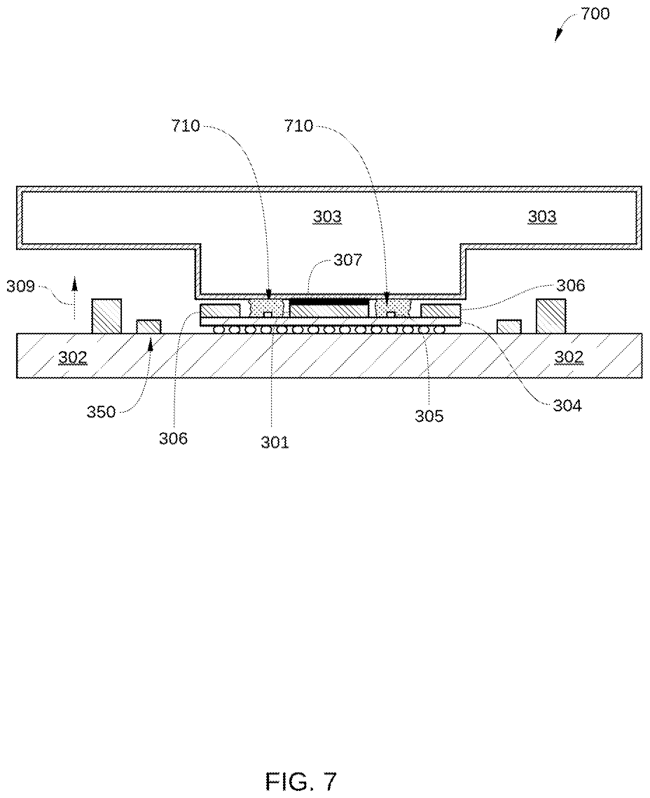

In some embodiments, an electronic device includes a single barrier seal that protects electronic components from shorting and prevents a liquid-metal TIM from being oxidized and/or chemically degraded via air-borne contaminants. One such embodiment is described below in conjunction with FIG. 7.

FIG. 7 is a conceptual cross-section of an electronic device 700 that includes thermal solution 703, liquid-metal TIM 307, and a single barrier seal 710, according to various embodiments. In the embodiment illustrated in FIG. 7, barrier seal 710 is disposed between thermal solution 703 and packaging substrate 304 so that electronic components are protected from liquid-metal TIM 307. In addition, barrier seal 710 forms an air-tight seal between thermal solution 703 and packaging substrate 304, so that liquid-metal TIM 307 is protected from air-borne contaminants. In some embodiments, barrier seal 710 includes one or more materials that provide electrical insulation of electronic components 305 and moisture resistance. In addition, barrier seal 710 includes one or more materials that prevent infiltration of humidity, oxygen, and/or other air-borne contaminants into liquid-metal TIM 307. Further, barrier seal 710 includes one or more materials that do not exert significant force against thermal solution 703 in direction 309 during operation of electronic device 700. For example, in some embodiments, barrier seal 710 includes one or more materials that soften or partially or completely change phase when heated during operation of electronic device 700 and/or are highly elastic.

In the embodiment illustrated in FIG. 7, barrier seal 710 is depicted encapsulating electronic components 305. In other embodiments, barrier seal 710 may be disposed between IC 301 and electronic components 305, and therefore not encapsulating electronic components 305. In such embodiments, barrier seal 710 prevents leaked and/or excess liquid-metal TIM 307 from reaching electronic components without forming an encapsulating seal, such as a seal that is similar first barrier seal 510 in FIG. 5.

### Lidded Package Barrier Seal Embodiments

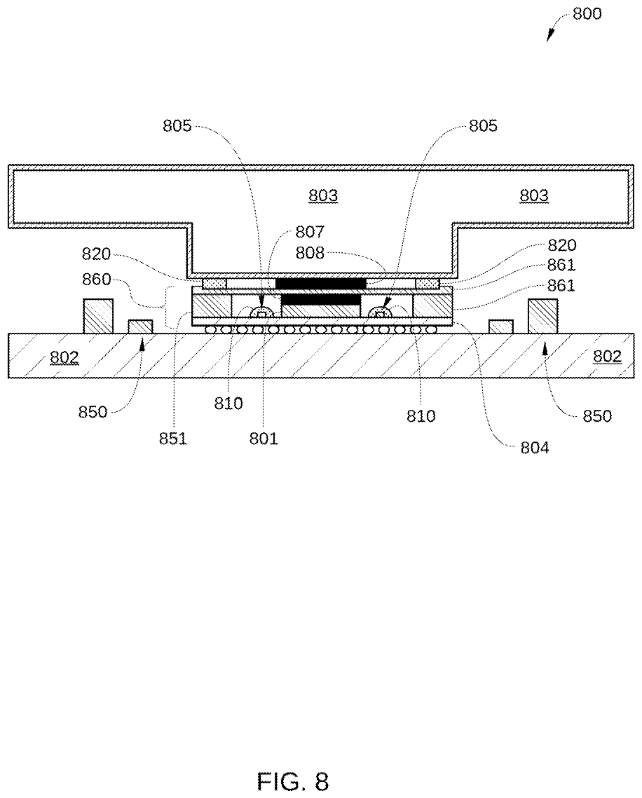

In some embodiments, an electronic device includes a lidded IC package that is thermally coupled to a heatsink or other thermal solution. In such embodiments, a liquid-metal TIM may be employed between the lidded IC package and the thermal solution and/or within the lidded IC package. Such embodiments are described below in conjunction with FIG. 8.

FIG. 8 is a conceptual cross-section of an electronic device 800 that includes a thermal solution 803 thermally coupled to a lidded IC package 860, according to various embodiments. In the embodiment illustrated in FIG. 8, lidded IC package 860 includes a lid 861 that encloses an IC 801 (such as a CPU, GPU, or other processor) mounted on a packaging substrate 804, along with various other electronic components 805, such as capacitors. As shown, IC 801 and electronic components 805 are disposed within lidded IC package 860. Lidded IC package 860 and other electronic components 850 are mounted on a PCB 802, such as memory devices and/or power devices associated with IC 801.

Lidded IC package 860 is coupled to thermal solution 803, for example via mounting screws (not shown) that press thermal solution 803 against lidded IC package 860. In the embodiment illustrated in FIG. 8, lid 861 of lidded IC package 860 includes a top portion and a sidewall portion, but in other embodiments, lid 861 is formed as a single piece. In either case, lid 861 encases and protects the various IC dies within lidded IC package 860, such as IC 801 and other electronic components 805.

In some embodiments, IC 801 is thermally coupled to lid 861 via a first liquid-metal TIM 807, such as a liquid metal that includes gallium, indium and tin. To prevent shorting of electronic components 805 and/or any other devices mounted on packaging substrate 304 within lidded IC package 860 by excess or leaked first liquid-metal TIM 807, electronic device 800 includes a first barrier seal 810 that is formed or deposited on electronic components 805 as shown. In some embodiments, first barrier seal 810 is consistent with barrier seal 310 of FIG. 3, and therefore can act as a physical barrier from excess first liquid-metal TIM 807 that can spill or leak during assembly, and/or leak at other times. It is noted that first liquid-metal TIM 807 is protected from humidity, oxygen, and other contaminants by lid 861. It is further noted that first barrier seal 810 is formed outside a perimeter of IC 801.

In some embodiments, lidded IC package 860 is thermally coupled to thermal solution 803 via a second liquid-metal TIM 808, such as a liquid metal that includes gallium, indium and tin. To prevent humidity, oxygen, and/or other contaminants from reacting with and/or contaminating second liquid-metal TIM 808, electronic device 800 includes a second barrier seal 820 that is formed or deposited on lid 861 and outside a perimeter of second liquid-metal TIM 808. In some embodiments, second barrier seal 820 is consistent with barrier seal 320 of FIG. 3, and therefore can act as a physical barrier that prevents excess or leaked second liquid-metal TIM 808 from reaching electronic components 850 mounted on PCB 802 and as a contamination barrier that prevents second liquid-metal TIM 808 from being exposed to humidity, oxygen, or other contaminants.

In the embodiment illustrated in FIG. 8, second barrier seal 820 is disposed in or completely fills a region between thermal solution 803 and lidded IC package 860 that corresponds to air gap 121 in FIG. 1. Further, in such embodiments, second barrier seal 820 can be formed entirely around a perimeter (not shown) of second liquid-metal TIM 808. Thus, in such embodiments, second barrier seal 320 acts as a barrier to air and/or air-borne contaminants from reaching second liquid-metal TIM 807. As a result, oxidation, hydrolysis, or other chemical degradation of second liquid-metal TIM 807, or any other unwanted chemical reactions, are prevented. It is noted that, to act as a barrier to air-borne contaminants, second barrier seal 820 is formed entirely and continuously around a perimeter of second liquid metal TIM 807 and fills an air gap (not shown) disposed between, for example, a surface of lid 861 and an opposing surface of thermal solution 803 (such as the surface of thermal solution 803 that faces lidded IC package 860).

In the embodiment illustrated in FIG. 8, electronic device 800 includes first barrier seal 810 within lidded IC package 860 and second barrier seal 820 formed or deposited on a surface of lidded IC package 860. In other embodiments, electronic device 800 includes first barrier seal 810 within lidded IC package 860 and no second barrier seal 820, and in other embodiments, electronic device 800 includes second barrier seal 820 formed or deposited on a surface of lidded IC package 860 and no first barrier seal 810 within lidded IC package 860.

In sum, one or more barrier seals are included in an electronic device with one or more high-power ICs that are thermally coupled to a heatsink or other thermal solution. In some embodiments, a first barrier seal is deposited or formed on electronic components proximate the high-power IC that can be shorted or damaged by leaked liquid-metal TIM. In some embodiments, a second barrier seal is deposited or formed to seal an air gap between an IC package and heatsink or thermal solution, thereby preventing a liquid-metal TIM from being exposed to humidity, air, and/or other contaminants.

At least one technical advantage of the disclosed design relative to the prior art is that the disclosed design prevents exposure of a liquid-metal TIM to moisture and/or other contaminants that can react with and alter the thermal conductivity of the liquid-metal TIM. Another technical advantage is that excess or leaked liquid-metal TIM cannot come into contact with capacitors or other electrical components that are mounted on the same packaging substrate as a high-power chip that is thermally coupled to a thermal solution via the liquid-metal TIM. These technical advantages provide one or more technological advancements over prior art approaches.

1. In some embodiments, an electronic device comprises: a printed circuit board; an integrated circuit that is coupled to the printed circuit board on a first side and a thermal solution on a second side; a thermal interface material that is disposed between the integrated circuit and the thermal solution; and a first barrier seal that is disposed around a perimeter of the integrated circuit and is electrically insulative.

2. The electronic device of clause 1, wherein the integrated circuit is mounted on a packaging substrate, and the first barrier seal is positioned to prevent one or more electrically conductive constituents included in the thermal interface material from contacting one or more electronic components that also are mounted on the packaging substrate.

3. The electronic device of clauses 1 or 2, wherein the first barrier seal is disposed on the one or more electronic components.

4. The electronic device of any of clauses 1-3, wherein the first barrier seal is positioned to prevent one or more electrically conductive constituents included in the thermal interface material from contacting one or more electronic components that are mounted on the printed circuit board.

5. The electronic device of any of clauses 1-4, further comprising a second barrier seal that is disposed around the perimeter of the integrated circuit and forms a seal between a surface of the thermal solution and a surface of an integrated-circuit package that includes the integrated circuit.

6. The electronic device of any of clauses 1-5, wherein the second barrier seal fills an air gap that is located between the surface of the thermal solution and the surface of the integrated-circuit package.

7. The electronic device of any of clauses 1-6, wherein the second barrier seal is disposed continuously around the perimeter of the integrated circuit.

8. The electronic device of any of clauses 1-7, wherein the surface of the integrated-circuit package comprises either a surface of a stiffener included in the integrated-circuit package or a surface of a packaging substrate included in the integrated-circuit package.

9. The electronic device of any of clauses 1-8, wherein the second barrier seal has a softening temperature that is less than or equal to an operating temperature of the integrated circuit.

10. The electronic device of any of clauses 1-9, wherein the second barrier seal comprises one of an elastic material or a hot melt adhesive.

11. The electronic device of any of clauses 1-10, wherein the integrated-circuit package comprises a lidded integrated-circuit package, and the surface of the integrated-circuit package comprises an outer surface of a lid of the integrated-circuit package.

12. The electronic device of any of clauses 1-11, wherein the thermal solution includes at least one of a heatsink, a vapor chamber, or a liquid cold plate.

13. The electronic device of any of clauses 1-12, wherein the first barrier seal does not contact the thermal solution.

14. The electronic device of any of clauses 1-13, wherein the integrated circuit is included in a lidded package, and the first barrier seal is disposed within the lidded package.

15. In some embodiments, an electronic device comprises: a printed circuit board; an integrated circuit that is coupled to the printed circuit board on a first side and a thermal solution on a second side; a thermal interface material that is disposed between the integrated circuit and the thermal solution; and a first barrier seal that is disposed around a perimeter of the integrated circuit and has a softening temperature that is less than or equal to an operating temperature of the integrated circuit.

16. The electronic device of clause 15, wherein the first barrier seal comprises a seal between a surface of the thermal solution and a surface of an integrated-circuit package that includes the integrated circuit.

17. The electronic device of clauses 15 or 16, further comprising a second barrier seal that is disposed around a perimeter of the integrated circuit and is electrically insulative.

18. The electronic device of any of clauses 15-17, further comprising one or more electronic components mounted on a packaging substrate, wherein the integrated circuit is mounted on the packaging substrate and wherein the second barrier seal is positioned to prevent one or more electrically conductive constituents included in the thermal interface material from contacting the one or more electronic components.

19. The electronic device of any of clauses 15-18, further comprising one or more electronic components mounted on a packaging substrate, wherein the integrated circuit is mounted on the packaging substrate and wherein the second barrier seal is disposed on the one or more electronic components mounted on the packaging substrate.

20. In some embodiments, a computing system comprises: a memory; and an electronic device that includes: a printed circuit board; an integrated circuit that is coupled to the printed circuit board on a first side and a thermal solution on a second side; a thermal interface material that is disposed between the integrated circuit and the thermal solution; and a first barrier seal that is disposed around a perimeter of the integrated circuit and is electrically insulative.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

While the preceding is directed to embodiments of the present disclosure, other and further embodiments of the disclosure may be devised without departing from the basic scope thereof, and the scope thereof is determined by the claims that follow.

What is claimed is:

1. An electronic device, comprising:
a printed circuit board;
an integrated circuit that is coupled to the printed circuit board on a first side and a thermal solution on a second side;
a thermal interface material that is disposed between the integrated circuit and the thermal solution; and
a first barrier seal that is disposed around a perimeter of the integrated circuit and is electrically insulative.

2. The electronic device of claim 1, wherein the integrated circuit is mounted on a packaging substrate, and the first barrier seal is positioned to prevent one or more electrically conductive constituents included in the thermal interface material from contacting one or more electronic components that also are mounted on the packaging substrate.

3. The electronic device of claim 2, wherein the first barrier seal is disposed on the one or more electronic components.

4. The electronic device of claim 1, wherein the first barrier seal is positioned to prevent one or more electrically conductive constituents included in the thermal interface material from contacting one or more electronic components that are mounted on the printed circuit board.

5. The electronic device of claim 1, further comprising a second barrier seal that is disposed around the perimeter of the integrated circuit and forms a seal between a surface of the thermal solution and a surface of an integrated-circuit package that includes the integrated circuit.

6. The electronic device of claim 5, wherein the second barrier seal fills an air gap that is located between the surface of the thermal solution and the surface of the integrated-circuit package.

7. The electronic device of claim 5, wherein the second barrier seal is disposed continuously around the perimeter of the integrated circuit.

8. The electronic device of claim 5, wherein the surface of the integrated-circuit package comprises either a surface of a stiffener included in the integrated-circuit package or a surface of a packaging substrate included in the integrated-circuit package.

9. The electronic device of claim 5, wherein the second barrier seal has a softening temperature that is less than or equal to an operating temperature of the integrated circuit.

10. The electronic device of claim 5, wherein the second barrier seal comprises one of an elastic material or a hot melt adhesive.

11. The electronic device of claim 5, wherein the integrated-circuit package comprises a lidded integrated-circuit package, and the surface of the integrated-circuit package comprises an outer surface of a lid of the integrated-circuit package.

12. The electronic device of claim 1, wherein the thermal solution includes at least one of a heatsink, a vapor chamber, or a liquid cold plate.

13. The electronic device of claim 1, wherein the first barrier seal does not contact the thermal solution.

14. The electronic device of claim 1, wherein the integrated circuit is included in a lidded package, and the first barrier seal is disposed within the lidded package.

15. An electronic device, comprising:
a printed circuit board;
an integrated circuit that is coupled to the printed circuit board on a first side and a thermal solution on a second side;
a thermal interface material that is disposed between the integrated circuit and the thermal solution; and
a first barrier seal that is disposed around a perimeter of the integrated circuit and has a softening temperature that is less than or equal to an operating temperature of the integrated circuit.

16. The electronic device of claim 15, wherein the first barrier seal comprises a seal between a surface of the thermal solution and a surface of an integrated-circuit package that includes the integrated circuit.

17. The electronic device of claim 15, further comprising a second barrier seal that is disposed around a perimeter of the integrated circuit and is electrically insulative.

18. The electronic device of claim 17, further comprising one or more electronic components mounted on a packaging substrate, wherein the integrated circuit is mounted on the packaging substrate and wherein the second barrier seal is positioned to prevent one or more electrically conductive constituents included in the thermal interface material from contacting the one or more electronic components.

19. The electronic device of claim 17, further comprising one or more electronic components mounted on a packaging substrate, wherein the integrated circuit is mounted on the packaging substrate and wherein the second barrier seal is disposed on the one or more electronic components mounted on the packaging substrate.

20. A computing system, comprising:
a memory; and
an electronic device that includes:
a printed circuit board;
an integrated circuit that is coupled to the printed circuit board on a first side and a thermal solution on a second side;
a thermal interface material that is disposed between the integrated circuit and the thermal solution; and
a first barrier seal that is disposed around a perimeter of the integrated circuit and is electrically insulative.
